(19) United States
(12) Patent Application Publication
(10) Pub. No.: US 2025/0326034 A1
(43) Pub. Date: Oct. 23, 2025

(54) 3D PRINTING USING ALD-COATED POWDER

(71) Applicant: Applied Materials, Inc., Santa Clara, CA (US)

(72) Inventors: Katherine E Woo, Santa Clara, CA (US); Jennifer Y Sun, Mountain View, CA (US)

(73) Assignee: Applied Materials, Inc., Santa Clara, CA (US)

(21) Appl. No.: 18/639,677

(22) Filed: Apr. 18, 2024

(51) Int. Cl. B22F 10/14; B22F 1/17; B22F 5/00; B33Y 10/00; H01J 37/32

(52) U.S. Cl. CPC B22F 10/14; B22F 1/17; B22F 5/00; H01J 37/32467; H01J 37/32495; B33Y 10/00

(57) ABSTRACT

Exemplary methods of forming a sintered semiconductor chamber component may include applying a binder solution and a ceramic-containing powder having a corrosion-resistant coating to a print bed to form a body of a semiconductor component. The methods may include sintering the body of the semiconductor component to form the semiconductor component from the ceramic-containing powder having the corrosion-resistant coating.

### TECHNICAL FIELD

The present technology relates to manufacturing processes for producing semiconductor chamber components. More specifically, the present technology relates to producing chamber components using additive manufacturing techniques.

### BACKGROUND OF THE INVENTION

Integrated circuits are made possible by processes which produce intricately patterned material layers on substrate surfaces. Producing patterned material on a substrate requires controlled methods of formation and removal of exposed material. Deposition and removal operations may include producing a local plasma in a processing region of a semiconductor processing chamber, for example, between a showerhead or gas distributor and a substrate support. Components of the semiconductor processing chamber may be or include a sintered composite material. Where the sintered composite material is exposed to corrosive species on a repeated basis, degradation of the components and contamination of substrates being processed may occur. Accordingly, a top coating may be provided to protect the underlying component from corrosion. However, the top coating may eventually be exhausted and require replacement.

Thus, there is a need for improved systems and system components that can be used to produce high quality devices and structures. These and other needs are addressed by the present technology.

### BRIEF SUMMARY OF THE INVENTION

Exemplary methods of forming a sintered semiconductor chamber component may include applying a binder solution and a coated powder to a print bed to form a body of a semiconductor component. The coated powder may include a core that may include one or both of a ceramic and a metal. The coated powder may include a corrosion-resistant coating disposed about the core. The methods may include sintering the body of the semiconductor component to form the semiconductor component from the coated powder.

In some embodiments, the binder solution and the coated powder may be premixed and applied to the print bed in a single stage. Applying the binder solution and the coated powder to the print bed may include applying the coated powder to the print bed and applying the binder solution to the coated powder using a jetting head of a 3D printer to form the body of the semiconductor component. The binder solution may include at least one of a carbohydrate, phosphoric acid, a polymer, colloidal silica, or acrylic acid. The core may include at least one of aluminum oxide (Al₂O₃), yttrium oxide (Y₂O₃), magnesium oxide (MgO), titanium oxide (TiO₂), aluminum nitride (AlN), silicon nitride (Si₃N₄) aluminum, magnesium, titanium, yttrium, an aluminum-magnesium alloy, tantalum, tungsten, hafnium, zirconium, nickel, or stainless steel. The corrosion-resistant coating may include one or more of an oxide, a nitride, an oxynitride, a fluoride, an oxyfluoride, a metal, or a carbide. The one or more of the oxide, the nitride, the oxynitride, the fluoride, the oxyfluoride, the metal, or the carbide may include at least one of aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), or magnesium (Mg).

Some embodiments of the present technology may encompass methods of forming a sintered semiconductor chamber component that may include applying an ink to a print bed to form a body of a semiconductor component. The ink may include a binder solution. The ink may include a coated powder. The coated powder may include a core that may include one or both of a ceramic and a metal. The coated powder may have a corrosion-resistant coating disposed about the core. The methods may include sintering the body of the semiconductor component to form the semiconductor component from the coated powder.

In some embodiments, the methods may include mixing the binder solution and the coated powder to form the ink prior to applying the ink to the print bed. The methods may include drying the ink prior to applying the ink to the print bed. Applying the ink may include distributing the ink on the print bed in dry form and applying a liquid-based printing solution using a jetting head. The printing solution may be applied in a shape of the body of the semiconductor component. The core may include at least one of aluminum oxide (Al₂O₃), yttrium oxide (Y₂O₃), magnesium oxide (MgO), titanium oxide (TiO₂), aluminum nitride (AlN), silicon nitride (Si₃N₄), aluminum, magnesium, titanium, yttrium, an aluminum-magnesium alloy, tantalum, tungsten, hafnium, zirconium, nickel, or stainless steel. The corrosion-resistant coating may include one or more of an oxide, a nitride, an oxynitride, a fluoride, an oxyfluoride, a metal, or a carbide. The one or more of the oxide, the nitride, the oxynitride, the fluoride, the oxyfluoride, the metal, or the carbide may include at least one of aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium oxide (ZrO₂), aluminum nitride (AlN), silicon nitride (SiN), tantalum nitride (TaN), titanium nitride (TIN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), or magnesium (Mg). The semiconductor component may include a lid, a nozzle, a faceplate, a gas distribution plate, a heater, a screw, a substrate support, a support platen, a liner, an edge ring, a process kit ring, or a lift pin.

Some embodiments of the present technology may encompass methods of forming a sintered semiconductor chamber component that may include applying a coated powder to a print bed of a 3D printer. The coated powder may include a core that may include one or both of a ceramic and a metal. The coated powder may have a corrosion-resistant coating disposed about the core. The methods may include applying a binder solution to the coated powder using a jetting head of the 3D printer to form a body of a semiconductor component. The methods may include sintering the body of the semiconductor component to form the semiconductor component from the coated powder.

In some embodiments, the semiconductor component may include a ceramic primary phase defining a plurality of grain boundaries and a secondary corrosion-resistant phase confined to the plurality of grain boundaries. The binder solution may include a liquid-based printing solution. The core may include at least one of aluminum oxide (Al₂O₃), yttrium oxide (Y₂O₃), magnesium oxide (MgO), titanium oxide (TiO₂), aluminum nitride (AlN), silicon nitride (Si₃N₄), aluminum, magnesium, titanium, yttrium, an aluminum-magnesium alloy, tantalum, tungsten, hafnium, zirconium, nickel, or stainless steel. The corrosion-resistant coating may include one or more of an oxide, a nitride, an oxynitride, a fluoride, an oxyfluoride, a metal, or a carbide. The one or more of the oxide, the nitride, the oxynitride, the fluoride, the oxyfluoride, the metal, or the carbide may include at least one of aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), or magnesium (Mg). The corrosion-resistant coating may include a first coating layer. The ceramic-containing powder may include a second coating layer.

Such technology may provide numerous benefits over conventional systems and techniques. For example, the methods and systems may provide a coated powder, a sintering blend, and a sintered material, exhibiting improved compatibility with plasma processing applications. For example, a powder may be chemically reduced to remove a passivation layer on the grains of the powder. In this way, a layer of material may be a coated directly onto a powder, for example, by atomic layer deposition. Chamber components may be formed by 3D printing a green body using the coated powders, which may improve the adhesion of the coated powders and improve the grain structure of the resultant component. Additionally, by sintering a 3D printed body formed from one or more coated powders, a sintering blend may permit the forming of a sintered material with tailored thermal, mechanical, and/or chemical properties. As such, the sintered material may exhibit improved thermal, mechanical, and/or chemical properties at elevated temperatures, including temperatures at which semiconductor processing operations are undertaken. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic view of an exemplary processing chamber according to some embodiments of the present technology.

FIG. 2 shows exemplary operations in a deposition method according to some embodiments of the present technology.

FIG. 3 show schematic views of a powder during operations in a deposition method according to some embodiments of the present technology.

FIG. 4 shows schematic views of an exemplary processing chamber component formed the method according to some embodiments of the present technology.

FIG. 5 shows exemplary operations of a method of forming a semiconductor chamber component according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

As part of semiconductor processing technology, deposition and removal operations may include producing a local plasma in a processing region of a semiconductor processing chamber, for example, between a showerhead or gas distributor and a substrate support. Components of the semiconductor processing chamber may be or include a sintered composite material. In order to protect the sintered composite material during operations using plasma, a top coating may be provided to protecting the underlying sintered composite material. The top coating may be a combination of materials, such as metal oxides. A first metal oxide may be deposited on the sintered composite material to promote adhesion between the sintered composite material and a second metal oxide that is corrosion-resistant. However, the top coating may be prone to degradation and/or deterioration during operations using plasma. Eventually, the top coating may be exhausted and the plasma may corrode the sintered composite material.

Conventional technologies have approached this limitation by controlling plasma operating conditions, for example, operating pressure, plasma power, duty cycle, or pulse frequency, which may restrict the operational window. Alternatively, conventional technologies may intermittently replace the top coating in order to maintain the corrosion protection, which require maintenance intervals during processing. The present technology may overcome these limitations by implementing improved deposition methods to remove a native passivation layer from the grains of the powder, which may permit deposition of materials directly onto the grains of the powder, for example, by atomic layer deposition. In addition, by sintering or pressing a coated powder, the distribution of corrosion-resistant material may be uniformly distributed through a sintered component, and may thereby reduce the potential for corrosion of the sintered component and extend the lifetime of the component with less maintenance intervals. This may enable preparation of coated powders for fabricating a variety of improved sintered components, including, but not limited to, plasma processing chamber components that exhibit improved thermal, mechanical, and chemical properties at conditions used for semiconductor processing. However, traditional sintering methods may not necessarily achieve the density and quality needed with these coated powders, and may fail to sufficiently adhere the coated powder particles to adhere to one another. Therefore, additive manufacturing techniques, such as 3D printing, may be used to form the green bodies of the chamber components prior to the sintering process. Such processes may provide better adhesion, density, and distribution of the coated powders prior to sintering and may result in higher quality chamber components that are resistant to processing chemistries. As a result, sintered components may be implemented in semiconductor processing chambers that are exposed to plasma operations.

After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

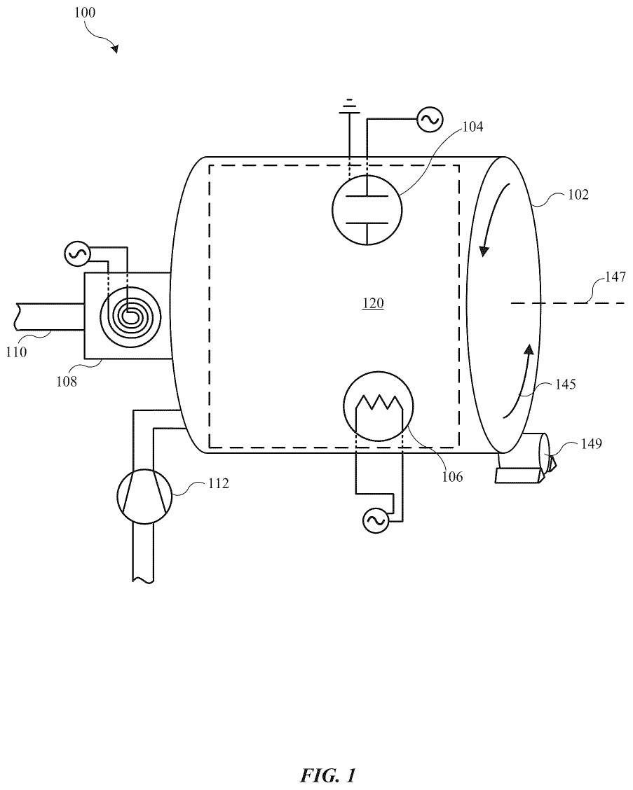

FIG. 1 shows a schematic view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form coated powders according to some embodiments of the present technology, although it is to be understood that the methods may similarly be performed in any chamber within which film formation may occur. For example, while the chamber 100 is illustrated in a horizontal rotating configuration, alternative embodiments may include a fluidized bed configuration or a plasma powder synthesis system. The processing chamber 100 may include a chamber body 102, a plasma system 104 inside the chamber body 102, a temperature control system 106, and a remote plasma system 108 coupled with the chamber body 102 and configured to provide plasma effluents to a processing region 120 of the chamber body 102.

A powder may be provided to the processing region 120 through a material feedthrough, such as a port or conduit, which may be sealed for processing using a slit valve, gate valve, or door. The powder may be mechanically mixed during processing. To that end, the processing region 120 or the chamber body 102 may be rotatable, as indicated by the arrow 145, about an axis 147, for example, by an electromechanical rotating element 149. Electromechanical rotating element 149 may be configured to rotate one or more structures internal to the chamber body 102, for example, by rotating the chamber body 102 about the axis 147. Alternatively, the powder may be mixed and suspended in the processing region 120 by convective action of gases introduced during a deposition process, for example, by fluidization that may be controlled to limit entrainment and powder loss.

Precursors, as described below, may be provided to the chamber 100 through a gas supply system 110. While FIG. 1 illustrates a single inlet for the gas supply system 110, the chamber 100 may include multiple gas inlets coupled with the chamber body 102 at one or more locations. For example, a plasma precursor may be introduced to the chamber body through the remote plasma system 108, while a second gas inlet may provide gases for which plasma dissociation would negatively impact the deposition process. Gases may be removed from the chamber body 102 by a gas removal system 112. The gas removal system 112 may include a vacuum system, configured to facilitate reduced pressure operation during deposition processes and to evacuate the chamber to remove process effluents and unreacted process gases. Measurement and control systems may be coupled with the chamber to measure operating pressure in one or more places, such as in the gas supply system 110, the gas removal system 112, or in the processing region 120. In another example, the temperature control system 106 may include temperature sensors and a heating element configured to provide heat to the processing region 120 or to remove heat from the processing region 120. In this way, the chamber 100 may implement controlled deposition and removal processes, such as plasma etching and removal, and atomic layer deposition.

As part of implementing plasma processing of powders in the chamber 100, in accordance with the methods described below, the plasma system 104 may be configured to form a plasma within the processing region 120. The plasma system 104 may be or include an indirect plasma system, such as an RF capacitively-coupled plasma, configured to form a plasma within the processing region 120 by generating sufficiently strong electric fields internal to the chamber body 102. In some embodiments, the plasma system 104 may be or include a direct plasma system, such that one or more electrode surfaces are disposed within the chamber body. In this way, the processing region 120 may be defined between a live electrode and a reference ground electrode of the plasma system 104. The plasma system 104 may also include control systems and power supply systems, such as impedance matching circuits and 13.56 MHz RF power supplies.

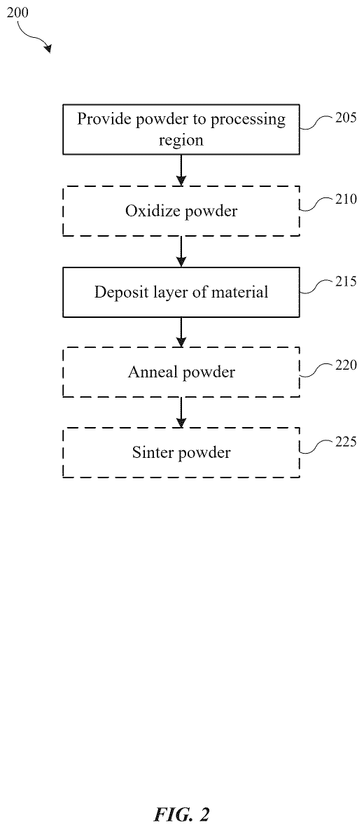

Similarly, the remote plasma system 108 may be or include a direct plasma system or an indirect plasma system, such as an inductively coupled RF plasma system or a capacitively coupled RF plasma system, which may be configured to decompose a precursor into plasma effluents that can be provided to the processing region 120. For example, the gas supply system 110 may include a quartz inlet tube coupled with a feedthrough to the chamber body 102. In such an arrangement, the remote plasma system 108 may be or include an CIP or a CCP system disposed external to the quartz inlet tube and configured to form a plasma within the quartz inlet tube. As further described in reference to FIG. 2, the precursor may include an inert carrier gas and a reaction precursor that may be or include a vapor or a gas. In this way, the remote plasma system 108 may form an indirect plasma in the precursor and may decompose the precursor. The decomposed precursor may be or include plasma effluents, which may be or include carrier gas, unreacted precursor, and plasma generated species. The plasma generated species may serve as reactants in a chemical reaction mediated deposition process, such as atomic layer deposition. As with the plasma system 104, remote plasma system 108 may also include control systems and power supply systems, such as impedance matching circuits and 13.56 MHz RF power supplies.

The temperature control system 106 may be configured to maintain an internal temperature in the processing region in accordance with a processing method. For example, as part of atomic layer deposition, a deposition substrate, such as a powder, may be heated to a reaction temperature at which a particular reaction product is favored. In an illustrative example, a surface reaction that forms a layer of material on the deposition substrate may be thermodynamically favored at an elevated temperature. As such, the temperature control system 106 may provide heat to the processing region. In some embodiments, the temperature control system may at least partially integrated into the plasma system 104. For example, an electrode of the plasma system 104 may incorporate heating and/or cooling elements, permitting the plasma system to operate within a range of operating temperatures.

In some embodiments, the chamber 100 may be configured to prepare coated powders for which the grains of the powder are coated with one or more layers of material. As described in reference to methods and systems, below, the chamber 100 may permit the preparation of improved coated ceramic-containing powders, which may be incorporated into sintering blends and sintered materials. Such sintered materials may exhibit improved thermal, mechanical, and/or chemical properties at processing conditions that are characteristic of plasma deposition and removal operations as part of semiconductor processing.

FIG. 2 shows exemplary operations in a deposition method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

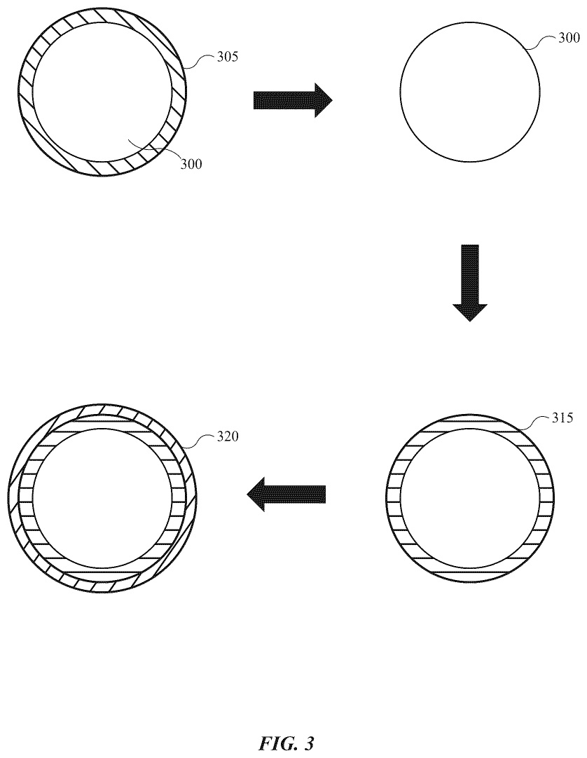

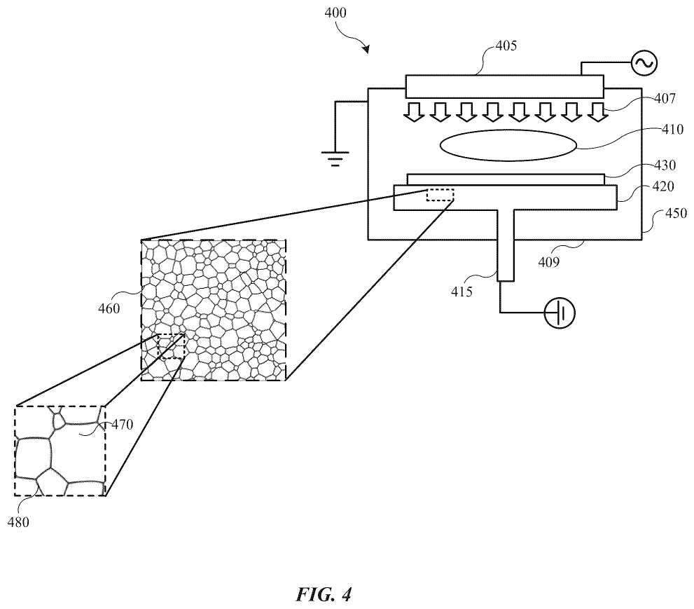

Method 200 describes operations shown schematically in FIG. 3, the illustrations of which will be described in conjunction with the operations of method 200. FIG. 4 illustrates an exemplary semiconductor processing system incorporating materials produced according to some embodiments of the method 200. It is to be understood that FIGS. 3-4 illustrate only partial schematic views, and a processing system may include subsystems as illustrated in the figures, as well as alternative subsystems, of any size or configuration that may still benefit from aspects of the present technology.

FIG. 3 shows schematic views of a powder 300 during operations of the deposition method 200 according to some embodiments of the present technology. In some embodiments, the method 200 may include one or more operations preceding those illustrated in FIG. 2. For example, one or more processes may be implemented to form the powder 300 from a feedstock material. For example, the powder 300 may be formed by chemically converting an oxide to a nitride, and may be cleaned, for example, by baking, etching, or degreasing. Examples of nitride synthesis may include, but are not limited to, carbo-thermal nitridization and/or direct nitridization. Furthermore, the powder 300 may be introduced into a processing chamber, such as the chamber 100, bearing a passivation layer 305. For example, the powder 300 may be or include aluminum nitride, which, through exposure to oxygen during cleaning or through exposure to air at ambient conditions, may develop an oxide passivation layer.

Method 200 may include additional operations prior to initiation of the listed operations. For example, additional processing operations may include preparing a particle, for example, by ball milling a material feedstock to prepare a powder of a characteristic size. As illustrated in FIG. 3, method 200 may include removing a passivation layer, such as a native oxide or surface oxide, prior to coating the particle. Removing the passivation layer may include providing hydrogen to the processing region of the chamber. Hydrogen may permit a hydrogen plasma, a hydrogen-rich plasma, or a trace-hydrogen plasma to be formed in the processing region, as an approach to chemically reducing the passivation layer 305. The hydrogen may be provided to the processing region of the chamber with an inert carrier gas. In plasma systems, inert carrier gases, also referred to as “forming gases”, facilitate plasma ignition and control of plasma conditions. For example, providing the hydrogen with a given inert gas fraction may permit the plasma to operate under controlled plasma conditions, such as ionization fraction, ion temperature, or electron temperature. Subsequent introducing hydrogen into the processing region, the method 200 may include striking a plasma in the processing region. The plasma may be or include a hydrogen plasma, and as such it may include energetic plasma species, such as hydrogen ions, hydrogen radicals, or metastable diatomic hydrogen. The hydrogen plasma may be formed in the processing region while the powder 300 is suspended in the processing region or passes through the processing region. The plasma treatment may be performed based on hydrogen supplied with a carrier gas, such as argon or helium, for generating the plasma, and the hydrogen may constitute a percentage material in the gas mixture.

At operation 205, method 200 may include delivering the powder to the processing region of the processing chamber, such as processing chamber 100 described above, or other chambers that may include components as described above. The powder 300 may include a plurality of individual particles. The particles making up the powder 300 may be any type of particle and may be a ceramic-containing powder in embodiments. For example, the particles of powder 300 may be or include, but are not limited to, aluminum oxide (Al₂O₃), yttrium oxide (Y₂O₃), magnesium oxide (MgO), titanium oxide (TiO₂), aluminum nitride (AlN), or silicon nitride (Si₃N₄), or any combination thereof. In some embodiments, the particles making up the powder 300 may be a metal-containing powder. For example, the particles of powder 300 may be or include, but are not limited to, aluminum, magnesium, titanium, yttrium, an aluminum-magnesium alloy, tantalum, tungsten, hafnium, zirconium, nickel, and/or stainless steel.

During method 200, the powder may be suspended in the processing region. As described in reference to FIG. 1, suspending the powder 300 may include rotating a chamber body of the deposition system, such as chamber body 102 of FIG. 1, to repeatedly pass the powder 300 through the processing region. In some cases, the powder 300 may be suspended by controlled gas flow to form a fluidized bed.

In some embodiments, method 200 may optionally include oxidizing the powder 300 at optional operation 210. Optional operation 210 may include introducing oxygen into the processing region of the chamber. Introducing oxygen into the processing region as part of plasma enhanced deposition may permit the formation of a controlled oxide layer on the powder 300. In contrast to the passivation layer 305, the controlled oxide layer may be formed under controlled conditions, such as in an oxygen plasma in the processing region, such that an oxide layer may be formed on the powder 300 with a characteristic and uniform thickness. Additionally or alternatively, optional operation 210 may include thermal oxidation of the powder 300 subsequent removal of the passivation film 305. A surface oxide layer may impart improved control of thermal, mechanical, and/or chemical properties in a sintered material formed using the powder 300, for example, by acting as a diffusion barrier or by defining grain boundaries in the sintered material. In this way, it may be advantageous to reduce the powder 300 to remove the passivation layer 305, and subsequently to oxidize the powder 300 under controlled conditions to reform an oxide layer.

Subsequent oxidizing the powder 300 at optional operation 210, method 200 may include forming a layer of material 315 on the powder 300 at operation 215. In some embodiments, forming the layer of material 315 on the powder 300 may include undertaking operations of an atomic layer deposition (ALD) process, whereby the grains of the powder 300 may be uniformly coated. For example, operation 215 may include introducing plasma effluents to the processing region. Plasma effluents may be or include plasma generated species that are formed by a remote plasma system, such as remote plasma system 108 of FIG. 1, in communication with the processing region. Introducing the plasma effluents may include introducing a carrier gas including the plasma effluents. In this way, introducing the plasma effluents into the processing region may expose the powder 300 to plasma effluents of one or more precursors that have been subjected to plasma decomposition. Plasma effluents, therefore, may be or include ions, activated radicals, metastable species, and other decomposition products, and may be characterized by average energy distribution lower than that of a direct plasma system. Exposing the powder 300 to the plasma effluents may, in turn, result in the formation of an adsorbed monolayer of plasma effluents on the surface of the grains of the powder 300 that serves as a precursor to the formation of the layer of material 315.

In a second operation of atomic layer deposition, the plasma effluents of the first precursor may be removed from the processing region by purging the processing region of gas, while retaining the powder 300 bearing the adsorbed monolayer. Purging the processing region may be implemented using a gas removal system, such as the gas removal system 112 of FIG. 1. Subsequent purging, a second precursor may be decomposed into second plasma effluents, such that the powder 300 is exposed to the second plasma effluents. The second precursor may be chosen such that it decomposes into plasma generates species that react with the monolayer adsorbed on the powder 300 to form the layer of material 315. Subsequent forming the layer of material 315, the unreacted plasma effluents and reaction byproducts may be removed by the gas removal system.

In some embodiments, the first and second precursors may be selected such that the layer of material 315 may be or include a corrosion-resistant additive to improve the mechanical properties of a sintered material formed by sintering the powder 300. In this way, one precursor may be or include a metal and the other precursor may be or include oxygen or nitrogen. The metal may be or include, for example, a rare earth element or a transition metal. For example, one of the precursors may include the metal, such as aluminum, yttrium, magnesium, titanium, erbium, lanthanum, scandium, or zirconium. The other precursor may include oxygen or nitrogen source and may be, for example, steam (H₂O), hydrogen peroxide (H₂O₂), oxygen (O₂), oxygen-based plasma, ozone (O₃), nitrous oxide (N₂O), molecular nitrogen (N₂), ammonia (NH₃), hydrazine (N₂H₄), or nitrogen-based plasma. Based on the precursors used, the layer of material 315 may be an oxide, a nitride, an oxynitride, an oxyfluoride, a carbide, a fluoride, a metal, and/or combinations thereof. For example, the layer of material 315 may be or include, but is not limited to, aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), and/or magnesium (Mg). In embodiments, the layer of material 315 may include multiple different oxide or nitride materials. For example, multiple layers of material may be formed on the powder 300. The layer of material 315 may include a same or different material as the ceramic-containing powder. In some embodiments, such as where the powder 300 is metal and the layer of material 315 is a metal, the layer of material 315 may form an alloy at the nano/micro-scale.

In some embodiments, either the first precursor or the second precursor may include fluorine, or other low melting point materials. For example, the fluorine-containing precursor may include, but is not limited to, aluminum fluoride (AlF₃), yttrium fluoride (YF₃), magnesium (MgF₂), titanium (TiF₄), erbium (ErF₃), lanthanum (LaF₃), scandium (ScF₃), or zirconium (ZrF₄). As discussed below, the powder 300 may be sintered to form a component for semiconductor processing. The use of fluorine in the powder 300 may allow the sintering of the powder 300 to proceed with increased efficiency due to the low melting point of the fluorine present in the layer of material 315.

In some embodiments, the constituent operations of the operation 215 may be repeated to deposit multiple monolayers, such that the layer of material 315 may be formed on a monolayer-by-monolayer basis, and the thickness of the layer of material 315 may be an integer multiple of the monolayer thickness and the number of repetitions of the operation 215. Furthermore, following operation 215, a second layer of material 320 may be formed overlying the layer of material 315, by repeating the operation with either the same set of first and second precursors or a different set of first and second precursors. For example, where the layer of material 315 may be or include aluminum oxide, the second material 320 may be or include a different oxide, such as yttrium oxide, magnesium oxide, aluminum nitride, or another metal oxide or metal nitride. As such, a coated powder formed from the powder 300 by the method 200 may include a controlled oxide layer, the layer of material 315, and one or more additional layers of different materials, such as the second layer of material 320.

A flowrate of the precursors introduced to the chamber may depend at least in part on one or more parameters of the chamber, the powder 300, or the method 200. For example, where the flowrate may be such that a plasma may form with a sufficient energy density or species density, such as ions, free electrons, or activated precursor, to facilitate, for example, reduction of the passivation layer 305 or deposition of the layer of material 315. In contrast, the flowrate of precursors may be limited by entrainment of the powder 300 in the flow, which may occur when the flowrate is excessively high. In such cases, the precursors may entrain the powder 300 and carry it out of the processing region, which is to be avoided.

Related to the flowrate of the precursors, a pulse size of the first precursor or of the second precursor may be less than or about 75 minutes. At times greater than 75 minutes, the powder 300 may be fully saturated and no longer accept the precursor to form a monolayer of material. Accordingly, the pulse size of the first precursor or of the second precursor may be less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less.

Similarly a pulse size of the purge gas to purge the first precursor may be less than or about 120 minutes, such as less than or about 110 minutes, less than or about 100 minutes, less than or about 90 minutes, less than or about 80 minutes, less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less. The purge may be a longer duration than the precursor in order to ensure the precursors are fully removed from the processing region.

During method 200, such as during operation 215, a temperature within the processing chamber may be maintained at less than or about 700° C. While higher temperatures may be employed, ALD depositions may be operated at temperatures less than or about 700° C., such as less than or about 675° C., less than or about 650° C., less than or about 625° C., less than or about 600° C., less than or about 575° C., less than or about 550° C., less than or about 525° C., less than or about 500° C., less than or about 480° C., less than or about 460° C., less than or about 440° C., less than or about 420° C., less than or about 400° C., less than or about 380° C., less than or about 360° C., less than or about 340° C., less than or about 320° C., less than or about 300° C., less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., less than or about 80° C., less than or about 60° C., less than or about 40° C., less than or about 20° C., or less.

Additionally, during method 200, such as during operation 215, a pressure within the processing chamber may be maintained at less than or about 50 mTorr. Again, while higher pressures may be employed, ALD depositions may be operated at pressures less than or about 50 mTorr, such as less than or about 45 mTorr, less than or about 40 mTorr, less than or about 35 mTorr, less than or about 30 mTorr, less than or about 25 mTorr, less than or about 20 mTorr, less than or about 15 mTorr, less than or about 10 mTorr, less than or about 7 mTorr, less than or about 5 mTorr, less than or about 3 mTorr, less than or about 1 mTorr, or less.

The layer of material 315 may be formed to a thickness of less than or about 3000 nm, such as less than or about 2750 nm, less than or about 2500 nm, less than or about 2250 nm, less than or about 2000 nm, less than or about 1750 nm, less than or about 1500 nm, less than or about 1250 nm, less than or about 1000 nm, less than or about 750 nm, less than or about 500 nm, less than or about 250 nm, less than or about 100 nm, or less. In embodiments, depending on the application, the layer of material 315 may be formed to a much smaller thickness, such as less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, less than or about 2 nm, less than or about 1 nm, or less. At thicknesses greater than 3000 nm, the layer of material 315 may make sintering the powder 300 more difficult due to the increased presence of material between the powder 300.

At optional operation 220, the method 200 may include annealing the powder 300. Annealing the powder 300 at optional operation 220 may alter the crystallinity of the layer of material 315 or may further enhance the thermal, mechanical, and or chemical properties of the layer of material 315. For example, the layer of material 315 may be formed as an amorphous structure, but the anneal at optional operation 220 may cause the layer of material 315 to transition to a crystalline structure. The powder 300 may be annealed in an oxygen-containing environment, in an inert environment, or in an active gas environment. In embodiments, the active gas environment may include but is not limited to, for example, a fluorine-containing environment. The fluorine-containing environment may include, but is not limited to, diatomic fluorine (F₂). In embodiments, the powder 300 may be annealed at a temperature greater than or about 300° C., such as greater than or about 350° C., greater than or about 400° C., greater than or about 450° C., greater than or about 500° C., greater than or about 550° C., greater than or about 600° C., greater than or about 650° C., greater than or about 700° C., or more, which may be greater than the temperature at operation 215. During optional operation 220, the pressure may be controlled, and the pressure may be maintained greater than, less than, or at about atmospheric pressure.

The method 200 and its constituent operations may provide one or more improvements to plasma enhanced deposition processes for depositing materials layers onto a powder by ALD. For example, the method 200 may provide a coated powder characterized by a core shell structure, where the core may be or include a ceramic material, such as aluminum nitride or any other ceramic material, with one or more shells, such as a transition metal oxide or a rare earth oxide. The shells may be precisely deposited, due to the layer-wise deposition of atomic layer deposition methods, such that the relative composition of the coated powder may be specified by repeating the operation 215 for a predetermined number of times. Furthermore, plasma removal of a native passivation layer 305 may improve control of surface chemistry and therefore improves the thermal, mechanical, and/or chemical properties of sintered materials formed using coated powders.

As described below, the coated powder may be prepared to provide improved thermal, mechanical, and/or chemical properties to a material formed by sintering or pressing the coated powder. To that end, the method 200 may be implemented to prepare multiple coated powders, to be combined into a sintering mix. For example, a first coated powder may be or include an aluminum nitride powder coated by a layer of yttrium oxide. A second coated powder may be or include an aluminum nitride powder coated by a layer of titanium oxide. The sintering mix may then be prepared by blending the first coated powder and the second coated powder, such that a sintered material formed using the sintering mix may be characterized by improved thermal, mechanical, and/or chemical properties, due in part to the improved control of relative composition of the coating material and in part to the improved distribution of the coating material in the sintering mix. Distribution of the coating material may be improved, in particular, relative to bulk powder blends that may undergo agglomeration or density segregation, as examples of phenomena that may limit the effectiveness of blending and negatively impact the material properties of sintered materials.

At optional operation 225, the method 200 may include sintering the powder 300, or sintering mix, to form a component for semiconductor processing. As will be described further with regard to FIG. 4, the component for semiconductor processing may be, but is not limited to, a lid, a nozzle, a face plate, a gas distribution plate, a heater, a screw, a substrate support, a support platen, a liner, an edge ring, a process kit ring, or a lift pin. These components are commonly exposed to corrosive plasma conditions and may require corrosion-resistant coatings. By using coated powders previously discussed, the corrosion-resistant material may be incorporated within the component for semiconductor processing and, therefore, provide increased corrosion resistance.

FIG. 4 shows schematic views of an exemplary plasma processing system including one or more components formed by the method according to some embodiments of the present technology. FIG. 4 further illustrates details relating to a semiconductor processing system 400, and one or more components that may be incorporated into system 400 that may be or include a sintered material. The sintered material, in turn, may be formed by sintering a coated powder, such as the coated powder prepared by the method 200. System 400 is understood to include any feature or aspect of a semiconductor processing chamber, and may be used to perform semiconductor processing operations including deposition, removal, and cleaning operations. System 400 may show a partial view of the chamber components being discussed and that may be incorporated in a typical semiconductor processing system, and may illustrate a view across a center of the pedestal and gas distributor, which may otherwise be of any size. Any aspect of system 400 may also be incorporated with other processing chambers or systems as will be readily understood by the skilled artisan.

System 400 may include a semiconductor processing chamber 450 including a showerhead 405, through which precursors 407 may be delivered for processing, and which may be configured to form a plasma 410 in a processing region between the showerhead 405 and a pedestal or substrate support 415. The showerhead 405 is shown at least partially internal to the chamber 450, and may be understood to be electrically isolated from the chamber 450. In this way, the showerhead 405 may act as a live electrode or as a reference ground electrode of a direct plasma system to expose a substrate held on the substrate support 415 to plasma generated species. The substrate support 415 may extend through the base of the chamber 450. The substrate support 415 may include a support platen 420, which may hold a semiconductor substrate 430 during deposition or removal processes used to form patterned structures on the semiconductor substrate 430. In some embodiments, the substrate support 415 may be or form an electrostatic chuck body or portion thereof.

The support platen 420 may be or include a sintered material formed from coated powder prepared in accordance with embodiments of method 200. The support platen 420 may incorporate embedded electrodes to provide the electrostatic field employed to hold the semiconductor substrate, and may also include a thermal control system that may facilitate processing operations including, but not limited to, deposition, etching, annealing, or desorption. In some embodiments, the support platen 420 may incorporate a plate, a perforated plate, a mesh, a wire screen, or any other distributed arrangement of conductive elements. The embedded electrodes may be or include a tuning electrode to provide further control over the plasma 410, for example, by adjusting an electric field near the surface of the support platen. Similarly, a bias electrode and/or an electrostatic chucking electrode, may be coupled with the support platen 420. The bias electrode may be coupled with a source of electric power, such as a DC power, pulsed DC power, RF bias power, a pulsed RF source or bias power, or a combination of these or other power sources. In this way, the substrate support 415 and the support platen 420 may be used during plasma processing operations not only to hold the semiconductor substrate 430, but also to tune the conditions of the plasma 410. Tuning the conditions of the plasma may include implementing automatic impedance matching to maintain plasma conditions during plasma processing operations, for example, while the composition of the plasma 410 is varied or as the surface of the semiconductor substrate 430 changes, for example, due to deposition of dielectric films onto electrode surfaces. In this way, precise control of the plasma 410 may depend on the material properties of the substrate support 415 and the support platen 420.

In some cases, the support platen 420 or other chamber components may be formed from a sintered material. For example, a powder may be pressed into a mold and heated until grains of the powder fuse into the sintered material. As will be discussed in greater detail below, additive manufacturing techniques may be used to form a body, such as a green body, of a chamber component prior to the sintering process. Subsequent operations, such as annealing, machining, incorporating electrical components, and applying protective surface coatings, may be applied to finish the component, providing a working component that can be incorporated in a plasma system. An advantage of using a sintered material may include that a finished component may serve as a refractory conductor, with favorable thermal deformation characteristics and chemical resistance to plasma etching, as well as electrical conductivity.

Advantageously, sintered material formed from a coated powder prepared by the operations of the method 200, as described in reference to FIG. 2, may exhibit improved thermal, mechanical, and/or chemical properties at temperatures employed for plasma processing operations. For example, where a conventional sintered material may be formed from a blend of powders including a ceramic, incorporation of metal oxide or a rare earth oxide for corrosion resistance may be formed on a surface of the sintered material. In this way, the resulting sintered material may include a corrosion-resistant coating may be present only on a surface of the sintered material. Over time and over the course of semiconductor processing, the corrosion-resistant coating may be deteriorated and may eventually expose the underlying sintered material. For example, a portion of the corrosion-resistant coating at one location on the sintered component may be deteriorated and completely removed, while other locations of the corrosion-resistant coating may be relatively unbothered. However, the plasma environment may attack the uncoated portion of the sintered component and erode the sintered component. This erosion may damage the sintered component as well as introduce contaminants into the processing region.

In contrast, sintering the coated powders described in reference to FIG. 3, having one or more shells formed by the operations of the method 200, may result in an improved microstructure 460. By forming the sintered material with the coated powder, the core-shell structure may serve to control the distribution of the corrosion-resistant coating. The controlled distribution, in turn, may limit the migration of the corrosion-resistant coating during sintering, and may produce two principle phases in the microstructure 460. The microstructure 460 may include a primary phase 470 and a secondary phase 480, but may be substantially free of conductive grain inclusions. For example, the primary phase 470 may define a three-dimensional network of grain boundaries, and the secondary phase 480 may be confined to the grain boundaries. The primary phase 470 may be or include a ceramic material, such as that of the powder 300 of FIG. 3. The secondary phase 480 may be or include the material of the layers formed at operation 215 of FIG. 2 that has reacted with material of the powder core to form a layer of material, such as that of the layer of material 315 of FIG. 3. For example, where the core of the coated powder is aluminum nitride and the shell includes yttrium oxide, the secondary phase 480 may be or include yttrium aluminum oxide.

Advantageously, where the microstructure 460 confines the secondary phase 480 to the grain boundaries between grains of the primary phase 470, the sintered material may include the secondary phase 480 throughout the sintered material, which may be a component for semiconductor processing, such as the support platen 420 described previously, or other components, such as a lid, a nozzle, a face plate, a gas distribution plate, a heater, a screw, a substrate support, a liner, an edge ring, a process kit ring, or a lift pin. In this way, the secondary phase 480 may be distributed throughout the sintered material. Accordingly, the secondary phase 480, such as a corrosion-resistant material, may be present within and around the sintered material. Consequently, enhanced corrosion resistance through incorporation of corrosion-resistant material may be afforded compared to conventional technologies of coating sintered components with corrosion-resistant material.

Advantageously, forming the sintered material from the coated powder may permit the composition of the sintered material to be precisely controlled. In materials formed by sintering a blend of two powders, the composition may depend on precise measurement and handling of the blend prior to sintering. In contrast, a coated powder may be formed to have a precise composition, due in part to the precise nature of ALD techniques that form single layers of a coating material for each deposition cycle. In this way, each grain of the coated powder may include a precise quantity of a layer of material on the surface, providing a sintered material with a controlled composition that may be selected to impart improved thermal, mechanical, and chemical properties to the sintered materials.

As noted above, in some embodiments, the semiconductor chamber components may be formed from the powders disclosed here using additive manufacturing techniques. The use of additive manufacturing techniques may enable the green body of the chamber component to be formed with greater density and at a higher quality than achieved with traditional sintering techniques. Once the green body of the chamber component has been formed, the green body may be sintered to increase the density of the ceramic material, remove printing solutions, and form the final component.

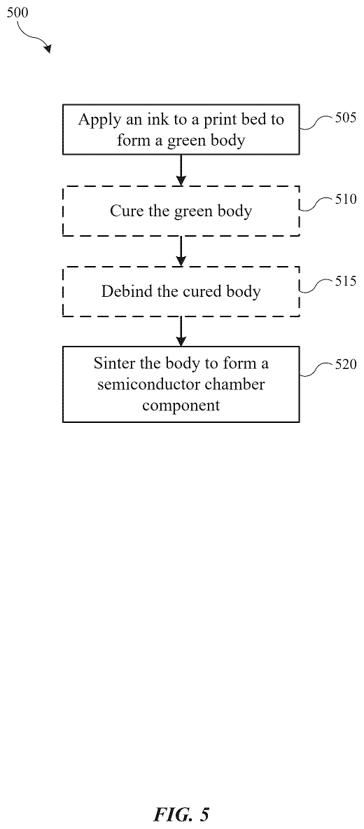

FIG. 5 shows operations of an exemplary method 500 of forming a sintered semiconductor chamber component according to some embodiments of the present technology. The sintered semiconductor chamber component may be a lid, a nozzle, a faceplate, a gas distribution plate, a heater, a screw, a substrate support, a support platen, a liner, an edge ring, a process kit ring, or a lift pin, such as described in relation to FIG. 4, and/or any other component that may form part of a semiconductor processing chamber. The method may be performed in various equipment, including a 3D printer and/or other additive manufacturing device according to embodiments of the present technology. Method 500 may include a number of optional operations, which may or may not be specifically associated with some embodiments of methods according to the present technology.

Method 500 may include optional operations prior to initiation of method 500, or the method may include additional operations. For example, method 500 may include operations performed in different orders than illustrated. In some embodiments, method 500 may include applying an ink to a print bed to form a body of a semiconductor component at operation 505.

The body of the semiconductor component may be a green body and may have substantially the same size and shape as a final chamber component produced using method 500. The ink may include a number of components. For example, the ink may include one or more coated powders. The coated powder may include a core that includes a ceramic and/or a metal and one or more corrosion-resistant coating layers disposed about the core. The core may be similar to or the same as powder 300. In some embodiments, the coated powder may include one or more metals and/or ceramics. For example, the coated powder may be or include aluminum oxide (Al₂O₃), yttrium oxide (Y₂O₃), magnesium oxide (MgO), titanium oxide (TiO₂), aluminum nitride (AlN), silicon nitride (Si₃N₄), aluminum, magnesium, titanium, yttrium, an aluminum-magnesium alloy, tantalum, tungsten, hafnium, zirconium, nickel, and/or stainless steel. The corrosion-resistant coating may be similar to or the same as layer of material 315 and/or 320. In some embodiments, the corrosion-resistant coating may be or include an oxide, a nitride, a fluoride, an oxyfluoride, a metal, a carbide, and/or an oxynitride. In a particular embodiment, the corrosion-resistant coating may include aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), and/or magnesium (Mg). In some embodiments, the ink may include multiple types of coated powders. As just one example, a first layer of a corrosion-resistant coating may be or include aluminum oxide and a second layer of a corrosion-resistant coating may be or include a different oxide, such as yttrium oxide, magnesium oxide, aluminum nitride, or another metal oxide or metal nitride. It will be appreciated that any number of coated powders (possibly with one or more uncoated powders) may be incorporated into the ink. In some embodiments, each metal and/or ceramic powder incorporated into the ink is coated with a corrosion-resistant material. Additionally, some embodiments may utilize one or more coated powders that include multiple layers of coating.

The ink may also include a binder solution that may help adhere the coated particles together to form a green body of the chamber component. The binder solution may include a carbohydrate (e.g., dextrin, maltodextrin, starch, etc.), phosphoric acid, a polymer (e.g., polyvinyl alcohol, polyethylene glycol, polyvinylpyrrolidone, etc.), colloidal silica, or acrylic acid. It will be appreciated that other binders may be used based on the composition of the coated powder. In some embodiments, the ink may include a liquid-based printing solution, such as water or other non-reactive liquid solution. In other embodiments, the liquid-based printing solution may be a separate component and/or omitted entirely.

In some embodiments, the ink may be applied in a single stage, such as by a print head or jetting head of a 3D printer. For example, the coated powder, binder solution, and/or liquid based printing solution may be deposited on a print bed of the 3D printer. The ink may be deposited as a number of layers to build up a final size and shape of the final chamber component, with the binder solution and/or liquid-based printing solution serving to adhere the coated powder together in the desired 3-dimensional shape to form a green body of the chamber component.

In other embodiments, the ink may be applied in multiple stages to form the green body. For example, the coated powder may be applied to the print bed prior to adding the binder solution and/or liquid-based printing solution. In some embodiments, the coated powder may be applied to the print bed in a general shape and/or size as the body of the chamber component being produced. The binder solution and/or liquid-based printing solution may then be applied to the coated powder, such as via a jetting head or other applicator of the 3D printer. A number of layers may be formed on top of one another to form the green body, with the binder solution and/or liquid-based printing solution serving to hold the various layers of the coated powder together in the green body.

In other embodiments, the coated powder may be distributed evenly across all or a portion of the surface of the print bed prior to application of the binder solution and/or liquid-based printing solution. For example, a thin layer of the coated powder may be distributed across the print bed, with a size and/or shape of the coated powder being different than that of the final chamber component. The binder solution and/or liquid-based printing solution may be applied using a jetting head or other component, with the binder solution and/or liquid-based printing solution being applied to the coated powder in a shape and size that matches a footprint of a portion of the final chamber component. A portion of the coated powder that receives the binder solution and/or liquid-based printing solution may mix with the binder solution and/or liquid-based printing solution, with the binder solution and/or liquid-based printing solution serving to adhere particles of the coated powder together to form a layer of the final chamber component. A portion of the coated powder that does not receive an application of the binder solution and/or liquid-based printing solution may remain unmixed with the binder solution and/or liquid-based printing solution and may not form a portion of the final chamber component. Another layer of coated powder may be applied atop the print bed and an additional application of binder solution and/or liquid-based printing solution may be applied to form an additional layer of the chamber component. This may be repeated until a green body having a full shape and thickness of the final chamber component is defined by a region of the multiple layers of a mixture of the coated powder, binder solution, and/or liquid-based printing solution.

In other embodiments, the coated powder and the binder solution may be premixed and applied to the print bed prior to application of the printing solution. The coated powder and binder solution may be premixed in wet or dry form. For example, the binder solution may be provided in a dry form and combined with the coated powder. The binder solution and coated powder may be mixed together, such as by using a grinder, ball mill, mortar and pestle, and/or other technique. In other embodiments, the binder solution and coated powder may be premixed in wet form. For example, the binder solution may be dissolved in a solvent (e.g., water) and combined with the coated powder. This liquid solution may be dried, such as via spray drying or other drying techniques. Regardless of how the binder solution and coated powder are mixed, the dried mixture may then be distributed about the print bed, such as in a thin layer of the mixture. The liquid-based printing solution may be applied using a jetting head or other component, with the liquid-based printing solution being applied to the dried mixture in a shape and size that matches a footprint of a portion of the final chamber component. A portion of the dried mixture that receives the liquid-based printing solution may mix with the liquid-based printing solution, with the liquid-based printing solution serving to adhere particles of the coated powder together to form a layer of the final chamber component. A portion of the dried mixture that does not receive an application of the liquid-based printing solution may remain unmixed with the liquid-based printing solution and may not form a portion of the final chamber component. Another layer of the dried mixture may be applied atop the print bed and an additional application of liquid-based printing solution may be applied to form an additional layer of the chamber component. This may be repeated until a green body having a full shape and thickness of the final chamber component is defined by a region of the multiple layers of a mixture of the coated powder, binder solution, and liquid-based printing solution.

After the green body of the chamber component has been formed, method 500 may include curing the green body at operation 510. Curing the green body may include, for example, heating all or a portion of the green body to a temperature in which the binder solution may be thermally activated by solvent evaporation, polymerization, cross-linking, or other mechanisms to strengthen the green body. The green body may be cured once fully printed and/or may be cured one or more layers at a time. The cure temperature may vary based on the composition of the binder solution, but may be between 175° C. and 800° C. in some embodiments. Once cured, the cured chamber component may go through a debinding process at operation 515 to form a brown chamber component. Debinding may include, for example, applying heat to the cured chamber component to thermally decompose and/or burn out the binder. In some embodiments, the cured chamber component may be heated to between about 400° C. and 800° C. to produce the brown chamber component.

After forming the green body, curing, and/or debinding the body of the chamber component, the body of the chamber component may be sintered at operation 520. Sintering may involve heating the body of the chamber component to a temperature that is below the melting point of the coated powder to increase the density of the chamber component. For example, the body of the chamber component may be heated to a high temperature (oftentimes within 100° C., within 75° C., within 50° C., within 25° C., within 10° C., or less of the melting point of the ceramic material), followed by dwelling and furnace cooling. The sintering step may increase the density of the part by mass transport across the boundaries of ceramic particles. In some embodiments, sintering may be completed after a curing and/or debinding process. In other embodiments, the sintering process may be formed directly to the green body. For example, the heat applied to the green body may, in addition to densifying the ceramic material (and corrosion-resistant coating), remove all, substantially all, or a portion of the binder solution and/or liquid-based printing solution from the body. Such sintering may be done in a single heat treatment process and/or may be done in stages. For example, the application of heat may be adjusted in stages during sintering to effectively perform the curing, debinding, and densifying processes.

The 3D printed, sintered chamber component may have an improved density compared to ceramic components produced using traditional sintering techniques. Additionally, by forming the sintered chamber component from the coated powders described herein, the grain structure of the sintered chamber component may be improved. For example, the grain structure of the sintered chamber component may include a ceramic primary phase defining a plurality of grain boundaries and a secondary corrosion-resistant phase confined to the plurality of grain boundaries. Such a grain structure may ensure that the sintered chamber component may be substantially free of conductive grain inclusions. Advantageously, where the microstructure confines the secondary phase to the grain boundaries between grains of the primary phase, the sintered chamber component may include the secondary phase throughout the sintered material, which may ensure that the secondary phase is distributed throughout the sintered material. Accordingly, the secondary phase may be present within and around the sintered material. This may provide the sintered chamber component with enhanced corrosion resistance compared to conventional technologies of coating sintered components with corrosion-resistant material.

Additionally, forming the sintered material from the coated powder using 3D printing techniques may permit the composition of the sintered material to be precisely controlled. In materials formed by sintering a blend of two powders, the composition may depend on precise measurement and handling of the blend prior to sintering. In contrast, a coated powder may be formed to have a precise composition, due in part to the precise nature of ALD techniques that form single layers of a coating material for each deposition cycle. In this way, each grain of the coated powder may include a precise quantity of a layer of material on the surface, providing a sintered material with a controlled composition that may be selected to impart improved thermal, mechanical, and chemical properties to the sintered materials.

Additionally, in some embodiments, the grain structure produced using 3D printing techniques with the coated powders may result in the first and second phases being distributed more uniformly or homogeneously throughout the sintered material. For example, with traditional 3D printing techniques using uncoated powders, the use of multiple types of powders may result in an uneven distribution of the two powders. For example, some grains of a first powder may contact only other grains of the first powder, while other grains of the first powder may contact grains of a second powder, exclusively or in addition to grains of the first powder. This may result in regions of the sintered material that have greater concentrations of one powder material than the other and may create a final sintered component with an irregular grain structure that may negatively impact the thermal or other properties of the sintered component. In contrast, by using the coated powders described herein, it can be ensured that each primary phase may form a core that may be encapsulated by a shell of the secondary phase, with each secondary phase. In other words, between adjacent primary phases are two secondary phase boundaries throughout the sintered chamber component. The consistent grain structure may improve the performance of the sintered chamber component, such as by improving control over the electrical and/or thermal conductivity properties of the resultant component.

The use of 3D printing (or other additive manufacturing techniques) may provide further benefits over using conventional forming and sintering techniques. For example, the use of 3D printing may enable the fabrication of chamber components having more complex geometries than those produced by traditional machining processes. Internal channels, voids, and/or other areas may be formed without the need for tool access, which may help eliminate seams formed when joining multiple pieces of material to form a part with the internal volumes. Additionally, 3D printing techniques may eliminate and/or reduce the need for some finishing steps, such as grinding, which may help increase the fabrication time of the components.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a cutout” includes a plurality of such cutouts, and reference to “the flange” includes reference to one or more flanges and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A method of forming a sintered semiconductor chamber component, comprising:
applying a binder solution and a coated powder to a print bed to form a body of a semiconductor component, wherein the coated powder comprises:
a core comprising one or both of a ceramic and a metal; and
a corrosion-resistant coating disposed about the core; and
sintering the body of the semiconductor component to form the semiconductor component from the coated powder.

2. The method of forming a sintered semiconductor chamber component of claim 1, wherein:
the binder solution and the coated powder are premixed and applied to the print bed in a single stage.

3. The method of forming a sintered semiconductor chamber component of claim 1, wherein:
applying the binder solution and the coated powder to the print bed comprises:
applying the coated powder to the print bed; and
applying the binder solution to the coated powder using a jetting head of a 3D printer to form the body of the semiconductor component.

4. The method of forming a sintered semiconductor chamber component of claim 1, wherein:
the binder solution comprises at least one of a carbohydrate, phosphoric acid, a polymer, colloidal silica, or acrylic acid.

5. The method of forming a sintered semiconductor chamber component of claim 1, wherein:
the core comprises at least one of aluminum oxide (Al₂O₃), yttrium oxide (Y₂O₃), magnesium oxide (MgO), titanium oxide (TiO₂), aluminum nitride (AlN), silicon nitride (Si₃N₄), aluminum, magnesium, titanium, yttrium, an aluminum-magnesium alloy, tantalum, tungsten, hafnium, zirconium, nickel, or stainless steel.

6. The method of forming a sintered semiconductor chamber component of claim 1, wherein:
the corrosion-resistant coating comprises one or more of an oxide, a nitride, an oxynitride, a fluoride, an oxyfluoride, a metal, or a carbide.

7. The method of forming a sintered semiconductor chamber component of claim 6, wherein:
the one or more of the oxide, the nitride, the oxynitride, the fluoride, the oxyfluoride, the metal, or the carbide comprises at least one of aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), or magnesium (Mg).

8. A method of forming a sintered semiconductor chamber component, comprising:
applying an ink to a print bed to form a body of a semiconductor component, wherein the ink comprises:
a binder solution; and
a coated powder, the coated powder comprising:
a core comprising one or both of a ceramic and a metal; and
a corrosion-resistant coating disposed about the core; and
sintering the body of the semiconductor component to form the semiconductor component from the coated powder.

9. The method of forming a sintered semiconductor chamber component of claim 8, further comprising:
mixing the binder solution and the coated powder to form the ink prior to applying the ink to the print bed.

10. The method of forming a sintered semiconductor chamber component of claim 9, further comprising:
drying the ink prior to applying the ink to the print bed.

11. The method of forming a sintered semiconductor chamber component of claim 8, wherein:
applying the ink comprises:
distributing the ink on the print bed in dry form; and
applying a liquid-based printing solution using a jetting head, wherein the printing solution is applied in a shape of the body of the semiconductor component.

12. The method of forming a sintered semiconductor component of claim 8, wherein:
the core comprises at least one of aluminum oxide (Al₂O₃), yttrium oxide (Y₂O₃), magnesium oxide (MgO), titanium oxide (TiO₂), aluminum nitride (AlN), silicon nitride (Si₃N₄), aluminum, magnesium, titanium, yttrium, an aluminum-magnesium alloy, tantalum, tungsten, hafnium, zirconium, nickel, or stainless steel; and
the corrosion-resistant coating comprises one or more of an oxide, a nitride, an oxynitride, a fluoride, an oxyfluoride, a metal, or a carbide.

13. The method of forming a sintered semiconductor chamber component of claim 12, wherein:
the one or more of the oxide, the nitride, the oxynitride, the fluoride, the oxyfluoride, the metal, or the carbide comprises at least one of aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), or magnesium (Mg).

14. The method of forming a sintered semiconductor chamber component of claim 8, wherein:
the semiconductor component comprises a lid, a nozzle, a faceplate, a gas distribution plate, a heater, a screw, a substrate support, a support platen, a liner, an edge ring, a process kit ring, or a lift pin.

15. A method of forming a sintered semiconductor chamber component, comprising:
applying a coated powder to a print bed of a 3D printer, the coated powder comprising:
a core comprising one or both of a ceramic and a metal; and
a corrosion-resistant coating disposed about the core; and
applying a binder solution to the coated powder using a jetting head of the 3D printer to form a body of a semiconductor component; and
sintering the body of the semiconductor component to form the semiconductor component from the coated powder.

16. The method of forming a sintered semiconductor chamber component of claim 15, wherein:
the semiconductor component comprises:
a ceramic primary phase defining a plurality of grain boundaries; and
a secondary corrosion-resistant phase confined to the plurality of grain boundaries.

17. The method of forming a sintered semiconductor chamber component of claim 15, wherein:
the binder solution comprises a liquid-based printing solution.

18. The method of forming a sintered semiconductor chamber component of claim 15, wherein:
the core comprises at least one of aluminum oxide (Al₂O₃), yttrium oxide (Y₂O₃), magnesium oxide (MgO), titanium oxide (TiO₂), aluminum nitride (AlN), silicon nitride (Si₃N₄), aluminum, magnesium, titanium, yttrium, an aluminum-magnesium alloy, tantalum, tungsten, hafnium, zirconium, nickel, or stainless steel; and
the corrosion-resistant coating comprises one or more of an oxide, a nitride, an oxynitride, a fluoride, an oxyfluoride, a metal, or a carbide.

19. The method of forming a sintered semiconductor chamber component of claim 18, wherein:
the one or more of the oxide, the nitride, the oxynitride, the fluoride, the oxyfluoride, the metal, or the carbide comprises at least one of aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), zirconium oxide (ZrO₂), aluminum nitride (AlN), silicon nitride (SiN), tantalum nitride (TaN), titanium nitride (TiN), zirconium nitride (ZrN), aluminum oxyfluoride (AlOF), yttrium oxyfluoride (YOF), aluminum fluoride (AlF₃), yttrium fluoride (YF₃), magnesium fluoride (MgF₂), magnesium oxyfluoride (MgOF), erbium oxyfluoride (ErOF), scandium fluoride (ScF₃), silicon carbide (SiC), tungsten carbide (WC), silicon (Si), aluminum (Al), yttrium (Y), or magnesium (Mg).

20. The method of forming a sintered semiconductor chamber component of claim 15, wherein:
the corrosion-resistant coating comprises a first coating layer; and
the coated powder comprises a second coating layer.
